(19) United States
(12) Patent Application Publication
(10) Pub. No.: US 2008/0212625 A1
(43) Pub. Date: Sep. 4, 2008

(54) SEMICONDUCTOR DEVICE

(75) Inventors: Sataro YAMAGUCHI, Aichi (JP); Yoichi Okamoto, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: Kabusiki Kaisha Y.Y.L., Tokyo (JP)

(21) Appl. No.: 12/013,615

(22) Filed: Jan. 14, 2008

(30) Foreign Application Priority Data
Jan. 15, 2007 (JP) 2007-005381
Mar. 20, 2007 (JP) 2007-072736
Jan. 4, 2008 (JP) 2008-000187

(51) Int. Cl. H01S 5/024; H01L 33/00; H01L 23/38

(52) U.S. Cl. 372/34; 257/712; 257/99; 257/E33.075; 257/E23.082

(57) ABSTRACT

Disclosed is a semiconductor apparatus comprising an N-type material which cools a silicon semiconductor using the current flowing through the silicon semiconductor.

### REFERENCE TO RELATED APPLICATION

This application is based upon and claims the benefit of the priorities of Japanese patent applications No. 2007-5381, filed on Jan. 15, 2007, No. 2007-72736, filed on Mar. 20, 2007 and No. 2008-187, filed on Jan. 4, 2008, the disclosures of which are incorporated herein in theirs entirety by reference thereto.

### FIELD OF THE INVENTION

This invention relates to a semiconductor apparatus and, more particularly, to a cooling structure therefor.

### BACKGROUND OF THE INVENTION

A cooling system equipped with a Peltier element has been used for cooling a semiconductor apparatus, such as CPU. There is provided a power supply for the Peltier element other than a power supply connected to the CPU. The CPU is provided with a heat radiating fin. Cooling is essential for a power device. A small sized power device is sometimes provided with a heat radiating surface having a volume more then 100 times that of the power device. The operating principle of the Peltier element is now briefly described. FIG.7 schematically shows the heat flow flux for the Peltier element and, more specifically, the current and the heat flux in the Peltier element. The current flowing direction is reversed depending on the polarity of the Peltier material, that is, on whether the material is of the N-type or the P-type. However, the heat flux is not changed. Heat conduction is from a high temperature side towards a low temperature side, regardless of the current flowing direction. Since the Joule's heat is isometric, heat flows to both the low temperature side and the high temperature side. The Peltier effect transports heat from the low temperature side to the high temperature side. Hence, the Peltier element is termed a heat pump.

The above processes, namely the heat conduction, Joule's heat and the Peltier effect, may be represented by the following mathematical expressions:

Heat conduction: κ·∇T (1)

Joule's heat: η·I² (2)

Peltier effect: α·T·I (3)

where κ, η and α denote thermal conductivity, electrical resistivity and the Seebeck coefficient, respectively.

To increase the amount of heat flow flux transported by the Peltier effect, with lesser current, a material with small κ, low η and high α is desirable. For example, a bismuth-tellurium based material is preferentially used. This material is used not as a semiconductor material but as a material of the properties close to those of a metal, which properties may be obtained by addition of larger quantities of impurities. For quantitative evaluation of conditions, a coefficient of performance Z is introduced. The coefficient of performance Z is given by the following equation (4):

Z=α²/(κ·η) (4).

A higher value of Z indicates the high performance of the material. Since the unit of Z is [T⁻¹], Z is usually multiplied by absolute temperature to Z·T for evaluation as a dimensionless number. In calculations of, for example, the heat flow flux, ZT is used to stand for the coefficient of performance, while Z per se is not used.

Tremendous efforts are needed to search for a material with small κ, low η and high α. It is because these parameters represent tradeoff properties in the case of metallic or semiconductor materials. In short, it may be said in general that a material having high thermal conductivity exhibits low electrical resistivity, and a material with low electrical resistivity exhibits a low Seebeck coefficient. It is on extremely rare occasions that these transport coefficients are changed in unison in desired directions. Hence, the selection of a material is equivalent to searching for optimum values of the respective parameters. When decision is given on a new basic material, the respective parameters are measured, as the amounts of impurities are changed in a wide range, or the methods of fabrication are changed, in order to evaluate the materials. Hence, even granting that the basic physical values of a given material have been found, there is no alternative but to resort to experiments in order to determine whether or not the material in question is usable.

FIG.8A and FIG.8B show typical structures of conventional lateral and vertical power MOSFETs. It is noted that these figures are those that appeared in ‘Applications of Power MOSFETs’, edited by International Rectifier Japan, October 2003, pp. 13. With the lateral power MOSFET, the channel through which flows the current is located transversely, such as from the lest-side source to the right-side drain. There is no directivity between the source and the drain, that is, electrons may flow in either directions. With the vertical type, the source and the drain are located on upper and lower sides, respectively, and electrons flow vertically, as indicated by arrows in the drawing. There again is no directivity.

FIG.9 shows a typical structure of an IGBT (Insulated Gate Bipolar Transistor), which is disclosed in Hiroshi YAMAZAKI, ‘Introduction to Power MOSFET/IGBT’, published by NIKKAN KOGYO SHIMBUN-SHA, July 2002, pp. 12. With the IGBT, a P-type material is contacted with a collector, and hence the carrier density in the semiconductor is increased significantly, with the result that the ON-voltage is lowered as compared to that in the case of the MOSFET. Thus, the IGBT is now used extensively as a power device. However, for the above reason, the switching frequency may not be set to a value comparable with that of the MOSFET. The IGBT may still be run at a frequency higher than with the GTO (Gate Turn-Off Thyristor).

Electrodes of the power MOSFET are formed of nickel-plated copper, for instance. The current that allows for switching is about 100 A, for instance, only in case the heat sink is in operation satisfactorily. Cooling is essential for controlling the large current. The P- or N-types, as polarity types, may be defined on the basis of the positive or negative Seebeck coefficient, for instance.

From the relationship between the current directions and the Peltier heat flow flux, shown in FIG.7, it is seen that the Peltier heat is transported in the vertical MOSFET from the inside of the semiconductor to the drain, and hence the MOSFET is cooled by the current. However, with the IGBT, in which the P-type material is connected to the collector, heat is transported towards the inside of the semiconductor material.

With the diode, a similar heat flow is generated when the current flows therethrough. With both the IGBT and the diode, the direction of the heat flow flux is towards the PN junction. Thus, given the high resistance at the PN junction, the temperature of the PN junction is raised suddenly with an increasing current. This is probably one of the reasons the on-resistance is increased suddenly with the increase in the current.

As for means for cooling a power device by a thermoelectric converting element, reference may be made to Patent Document 1, for instance.
[Patent Document 1] JP Patent Kokai JP-A-2003-179196
[Non-Patent Document 1] S. Yamaguchi et al. “Peltier current lead experiment and their applications for superconductor magnets”, Rev. Sci. Instrum., Vol. 75, pp. 207-212, 2004
[Non-Patent Document 2] T. Kawahara et al., “Thermoelectric properties of and Dopant distribution in SiC Thin Films”, Jpn. J. Appl. Phys., vol. 38, pp. 4852-4856, 1999
[Non-Patent Document 3] Y. Okamoto et al., “Infrared-reflection characterization of sintered SiC thermoelectric conductors with the use of a four-component effective medium model”, J. Applied Physics, vol. 85, pp. 6728-6737, 1999
[Non-Patent Document 4] Y. Okamoto et al., “Thermoelectric characteristics of silicon carbide sintered semiconductor dually added by nickel and silicon”, J. of Jpn. Soc. of Metallurgy, vol. 63, No. 11 (1999), pp. 1443-1447.
[Non-Patent Document 5] Glen A. Slack, “Thermal conductivity of Pure and Impure Silicon, Silicon Carbide and Diamond”, J. Applied phys., vol. 35, pp. 3460-3466, 1964
[Non-Patent Document 6] Y. Okamoto et al., “Temperature dependence of thermoelectric properties of SiC/B4C”, 13th Int. Conf. Thermoelectrics (AIP Conference Proc. 316), pp. 92-95, 1995
[Non-Patent Document 7] X. H. Wang et al., “Thermoelectric properties of SiC thick film deposited by thermal plasma physical vapor deposition”, Sci. Tech. Advanced Mat., vol. 4, pp. 167-172, 2003
[Non-Patent Document 8] Y. Okamoto et al., “Temperature dependence of thermoelectric properties of SiC/Al”, Proc. 14th Int. Conf. Thermoelectronics, pp. 269-273, 1996

### SUMMARY OF THE DISCLOSURE

The following analysis is given by the present invention. The disclosure of the above-mentioned Patent Document 1 and Non-Patent Documents 1 to 8 is incorporated herein by reference thereto.

In many cases, the power supply connected to the Peltier element is provided in a system different from a power supply system for a CPU or for a power device, because the operations of the two power supply systems are totally different from each other. For example, in a Peltier current lead (PCL), as used in a superconducting system (S. Yamaguchi et al., “Peltier current lead experiment and their applications for superconducting magnets”, Rev. Sci. Instrum., vol. 75, pp. 207-212, 2004), the power supply used for exciting a superconducting magnet is the same as the power supply used for Peltier-cooling a current lead. If the same power supply as the power supply for the superconducting magnet may be used for cooling as well, marked saving may be achieved in the power supply system.

Accordingly, it is an object of the present invention to provide a semiconductor apparatus in which the same power supply may be used in common for Peltier-cooling a semiconductor apparatus and for driving a semiconductor apparatus, thereby simplifying the power supply system.

In accordance with one aspect of the present invention, there is provided a semiconductor apparatus comprises: a semiconductor element; and a cooling system that cools the semiconductor element using the current flowing through the semiconductor element.

In the present invention, the cooling system includes an N-type material kept in contact with a silicon semiconductor.

In the present invention, the cooling system includes a material exhibiting relatively high thermal conductivity, relatively low electrical resistivity and a relatively high Seebeck coefficient.

In the present invention, the cooling system may include a metallic material. According to the present invention, the cooling system may comprise a copper alloy.

In the present invention, the cooling system may comprise silicon carbide. Alternatively, in the present invention, the cooling system may comprise aluminum nitride (AlN).

In the present invention, the semiconductor element includes a power MOSFET. In the present invention, a silicon substrate of the power MOSFET may be connected to a drain terminal of the power MOSFET via an N-type material. In the present invention, a drain electrode of the power MOSFET may include an N-type material.

In the present invention, the semiconductor apparatus is an IGBT (Insulated Gate Bipolar Transistor). In the present invention, the cooling system includes an N-type material arranged in contact with said IGBT via a metal layer. In the present invention, the silicon substrate may be connected to a collector terminal of the IGBT via an N-type material. In the present invention, the collector electrode of the IGBT may include an N-type material.

In the present invention, a heat sink may include an N-type material.

In accordance with another aspect of the present invention, there is provided a semiconductor apparatus wherein at least one of a P-type element and an N-type element which together form a PN junction, is provided with a thermoelectric semiconductor element of the polarity opposite to that of the aforementioned one element, with a metal layer in-between.

In the semiconductor apparatus according to the present invention, the P-type element forming the PN junction together with the N-type element is provided via a metal with an N-type thermoelectric semiconductor element on an upstream side of the current flowing through the PN junction.

In the semiconductor apparatus according to the present invention, the N-type element forming the PN junction together with the P-type element is provided via a metal with a P-type thermoelectric semiconductor element on a downstream side of the current flowing through the PN junction.

In the present invention, when the current flows through the PN junction, the thermoelectric semiconductor element operates as a Peltier cooling element.

In the present invention, at least one of a P-type element and an N-type element which together form a PN junction in at least one of a diode device, a LED (Light Emitting Diode) device and a semiconductor laser device, is provided with a thermoelectric semiconductor element of the polarity opposite to that of the aforementioned one element, with a metal layer in-between.

In the semiconductor apparatus according to the present invention, the P-type element forming the PN junction together with the N-type element is provided via a metal with an N-type thermoelectric semiconductor element on an upstream side of the current flowing through the PN junction.

In the semiconductor apparatus according to the present invention, the N-type element forming the PN junction together with the P-type element is provided via a metal with a P-type thermoelectric semiconductor element on a downstream side of the current flowing through the PN junction.

The meritorious effects of the present invention are summarized as follows.

According to the present invention, in which a semiconductor apparatus is cooled by exploiting the current flowing therein, it becomes possible to simplify the power supply system and to achieve saving in power consumption.

Still other features and advantages of the present invention will become readily apparent to those skilled in this art from the following detailed description in conjunction with the accompanying drawings wherein examples of the invention are shown and described, simply by way of illustration of the mode contemplated of carrying out this invention. As will be realized, the invention is capable of other and different examples, and its several details are capable of modifications in various obvious respects, all without departing from the invention. Accordingly, the drawing and description are to be regarded as illustrative in nature, and not as restrictive.

### BRIEF DESCRIPTIONS OF THE DRAWINGS

FIG.1 is a schematic side view showing the structure of the present invention.

FIG.2 is a schematic diagram illustrating the heat flow flux according to the present invention.

FIG.3 is a graph showing thermal conductivity of bulk SiC (Glen A. Slack, “Thermal conductivity of Pure and Impure Silicon, Silicon Carbide and Diamond”, J. Applied Phys., vol. 35, pp. 3460-3466, 1964, FIG.2).

FIG.4 is a graph showing temperature dependency of the Seebeck coefficient of a thin-film SiC of the N type, doped with nitrogen as impurity (X. H. Wang et al., “Thermoelectric properties of SiC thick film deposited by thermal plasma physical vapor deposition”, FIG.7, Sci. Tech. Advanced Mat., vol. 4, pp. 167-172, 2003).

FIG.5 is a graph showing temperature dependency of the electrical resistivity of a thin-film SiC of the N type, doped with nitrogen as impurity (X. H. Wang et al., “Thermoelectric properties of SiC thick film deposited by thermal plasma physical vapor deposition”, FIG.6, Sci. Tech. Advanced Mat., vol. 4, pp. 167-172, 2003).

FIG.6 is a graph showing temperature dependency of the power factor of a thin-film SiC of the N type, doped with nitrogen as impurity (X. H. Wang et al., “Thermoelectric properties of SiC thick film deposited by thermal plasma physical vapor deposition”, FIG.6, Sci. Tech. Advanced Mat., vol. 4, pp. 167-172, 2003).

FIG.7 is a schematic diagram illustrating the heat flow flux in a Peltier element.

FIGS.8A and 8B are schematic cross-sectional views of a lateral MOSFET and a vertical MOSFET, recited from ‘Applications of power MOSFETs’, edited by International Rectifier Japan, October 2004, pp. 13.

FIG.9 is a schematic a cross-sectional view of an IGBT, recited from Hiroshi YAMAZAKI, ‘Introduction to Power MOSFET/IGBT’, published by NIKKAN KOGYO SHIMBUN-SHA, July 2002, pp. 12.

FIG.10 is a schematic diagram illustrating the current flowing through a PN diode and the Peltier heat flow.

FIG.11 is a schematic diagram illustrating a modification of the present invention.

### PREFERRED MODES OF THE INVENTION

The present invention will now be described in detail with reference to accompanying drawings. According to the present invention, the current flowing through the power device is used for cooling. FIG.1 schematically shows the structure of an example of a cooling system according to the present invention. Referring to FIG.1, an N-type material 102 is used for Peltier cooling, in place of a conventional copper electrode, to which a drain of a MOSFET (a collector in the case of an IGBT) is connected. The silicon semiconductor 101 is cooled because heat is transported from the silicon semiconductor 101 to outside. The N-type material 102 has an area (or an area of cross section perpendicular to the direction of current flow), dimension of which is larger than that of the silicon semiconductor 101.

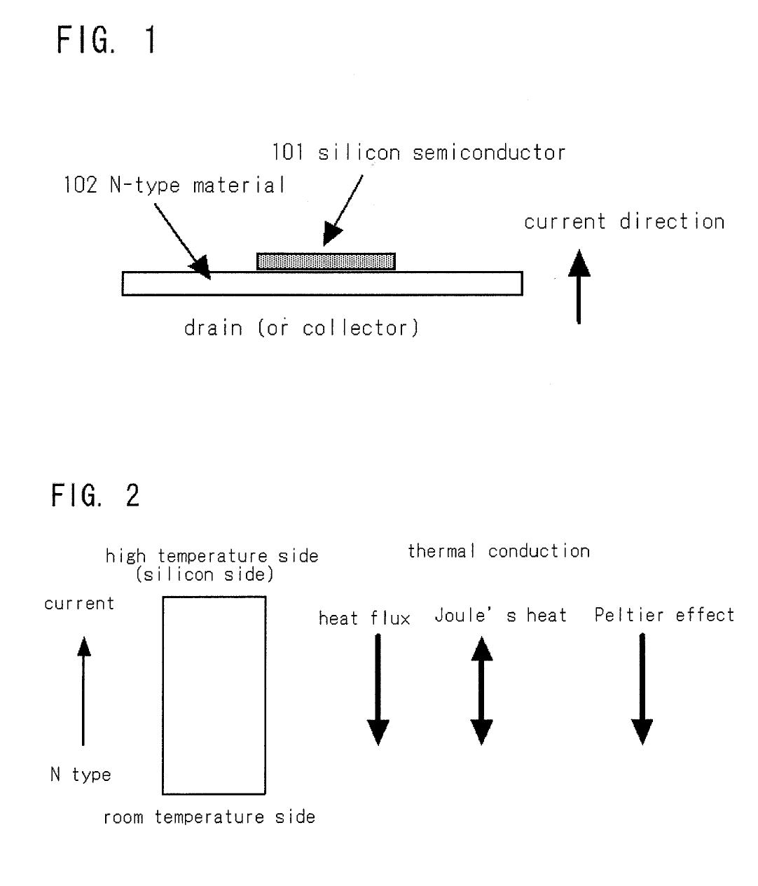

The N-type material 102 in FIG.1 has been selected in accordance with a selection principle different from the conventional selection principle for a Peltier material, as will now be explained with reference to FIG.2. The reason for this is that the temperature of the object to be cooled is higher than the room temperature.

With a conventional Peltier material, the direction of the heat flow flux by thermal conduction is opposite to that of the Peltier heat flow flux, in order to arrive at a temperature lower than the room temperature.

Also, since the N-type material is used, the heat flow flux by thermal conduction is from the silicon side to the room temperature side. In such system, the criterion for material selection is altered.

According to the present invention, the criterion for material selection is towards high κ, low η and high α. Since thermal conduction also contributes to cooling, such a material having high thermal conductivity is used. Hence, the conventional coefficient of performance for a Peltier material is unusable.

In the present invention, there is proposed a new coefficient of performance Y given by the following equation (5).

$$Y = \frac{κ \cdot {α}^{2}}{η} \qquad ( 5 )$$

According to the present invention, this Y is to be a criterion for evaluation. Hence, there is a possibility that a material different from the conventional material shall be used. It is noted that, in the case of a metallic material, such a material having high thermal conductivity is lower in general in electrical resistivity, so that, with the metallic material, the aforementioned contradiction may be made more moderate than with the commonly used Peltier material. As the material for a newly proposed Peltier element, a metallic material is used. It is well-known that, in case the transport phenomenon is by a degenerated electron gas, the electrical resistivity and the thermal conductivity follow the Wiedemann-Franz rule, which may be expressed by the equation (6):

κ·η=L·T (6)

where T is the absolute temperature, and L, termed the Lorenz number, may be expressed, in terms of the Boltzmann constant and electron charges, by the following equation:

$$L = {( \frac{π \cdot {k}_{B}}{{e}^{2}} )}^{2} / 3 = 2.45 \times {10}^{- 8} [ WW / {K}^{2} ] \qquad ( 7 )$$

It has been empirically known, and theoretically derived, that L is of approximately the same value for a plural number of metals. It is among guidelines to search for a metallic material having a high Seebeck coefficient. Constantan, a copper alloy used for a thermocouple, for example, is of the N type and has a Seebeck coefficient at room temperature of −42.7 mV/K, a value 100 or more times as high as that for pure copper. The electrical resistivity of constantan is 0.49 mW·m, a value 50 or more times as high as that of pure copper. Since it is felt that the Wiedemann-Franz rule gives good approximation, the coefficient of performance Y of constantan is higher than that of copper, if the electrical resistivity of constantan is assumed to be higher by ca. 50 times that of pure copper. Thus, constantan was used as metallic material.

Another example of the present invention will be described. Researches in silicon carbide (SiC) have so far been conducted extensively as a Peltier material. See for example T. Kawahara et al., “Thermoelectric properties of and Dopant distribution in SiC Thin Films”, Jpn. J. Appl. Phys., vol. 38, pp. 4852-4856, 1999, Y. Okamoto et al., “Infrared-reflection characterization of sintered SiC thermoelectric semiconductors with the use of a four-component effective medium model”, J. Applied Physics, vol. 85, pp. 6728-6737, 1999 and Y. Okamoto et al., “Thermoelectric characteristics of silicon carbide sintered semiconductor dually added by nickel and silicon”, J. of Jpn. Soc. of Metallurgy, vol. 63, No. 11 (1999), pp. 1443-1447.

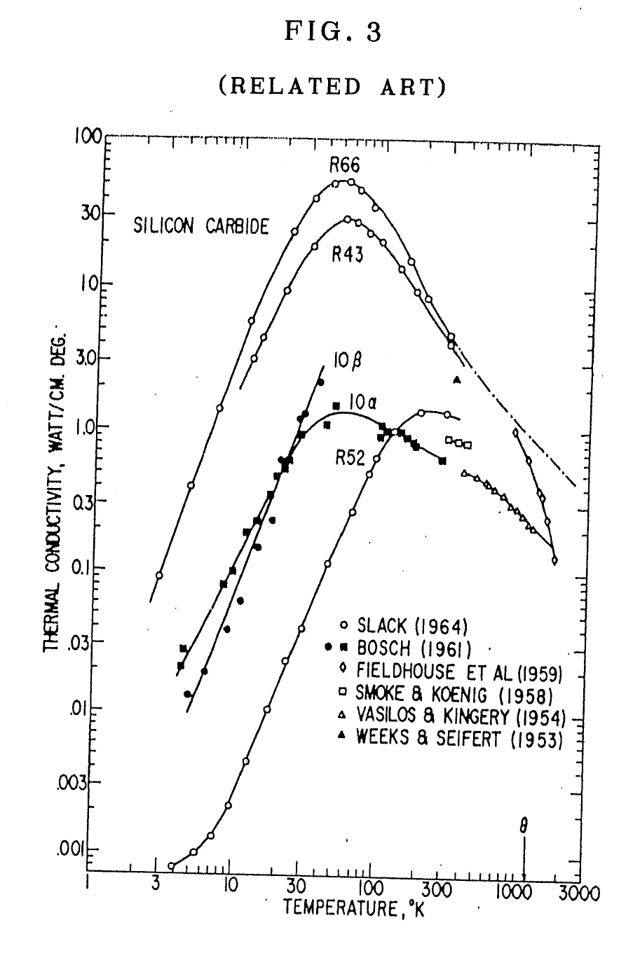

The reason is that silicon carbide (SiC) can be used under hostile conditions in a temperature range of from low temperatures to elevated temperature. By the above researches, the materials having a high Seebeck coefficient and low electrical resistivity have come to be manufactured, and hence the power factor(=) has become higher, but the material has thermal conductivity inherently higher than that of copper. In this consideration, the use of the material as the Peltier material has been abandoned for the most part until now. However, this property is rather desirable for the present invention, as discussed in the foregoing. FIG.3 shows thermal conductivity of SiC (Glen A. Slack, “Thermal conductivity of Pure and Impure Silicon, Silicon Carbide and Diamond”, J. Applied Phys., vol. 35, pp. 3460-3466, 1964). The thermal conductivity has been obtained not by an experiment for developing a Peltier material, but by an experiment for extensively searching for its physical properties. The mechanical strength of the samples, used for the experiment, is sufficient.

A sample of a mono-crystalline with low doping exhibits high thermal conductivity, whereas a sample with low thermal conductivity is polycrystalline.

For a range of 300K to 400K, the thermal conductivity of SiC ranges between 300 W/mk and 500 W/mk. This value range is higher than that of copper. On the other hand, the thermal conductivity for a polycrystalline sample ranges from 60 W/mk to 150 W/mk. In line with the search for a Peltier material, SiC was added by B4C as an impurity (Y. Okamoto et al., “Temperature dependence of thermoelectric properties of SiC/B4C”, 13^{th} Int. Conf, Thermoelectrics (AIP Conference Proc. 316), pp. 92-95, 1995). In this case, the polarity is the P-type. The thermal conductivity for this case is about equal to or even higher than the above value. In general, the thermal conductivity is more difficult to measure accurately than electrical values.

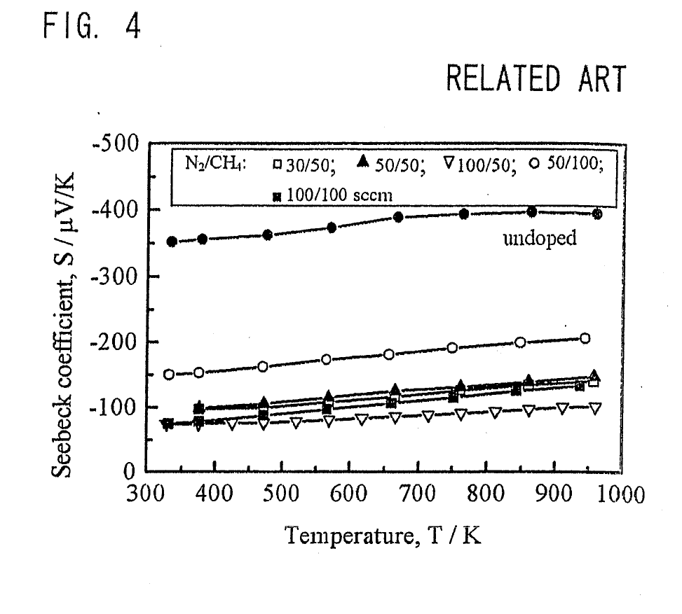

FIG.4 shows temperature dependency of the Seebeck coefficient (X. H. Wang et al., “Thermoelectric properties of SiC thick film deposited by thermal plasma physical vapor deposition”, Sci. Tech. Advanced Mat., vol. 4, pp. 167-172, 2003).

In this case, nitrogen is doped as impurity in a thin-film SiC. The sample in this case is of the N-type usable in the present example. In general, with SiC used for a semiconductor apparatus, the impurity is nitrogen, and hence SiC is of the N-type. However, polycrystalline Si, fabricated by sintering, often is of the P-type. The Seebeck coefficient of SiC is varied from −80 mV/K to −350 mV/K, depending on the amount of the impurity added. This tendency has been observed with a sintered sample that uses aluminum as impurity (Y. Okamoto et al., Temperature dependence of thermoelectric properties of SiC/Al”, Proc. 14^{th} Int. Conf. Thermoelectronics, pp. 269-273, 1996). However, in this case, the sample is of the P-type. Seeing that the Seebeck coefficient of copper, estimated to a larger possible value side, is approximately −0.5 mV/K, the Seebeck coefficient of the thin film Sic, doped with impurities, is larger by not less than two orders of magnitude than this estimated value for copper.

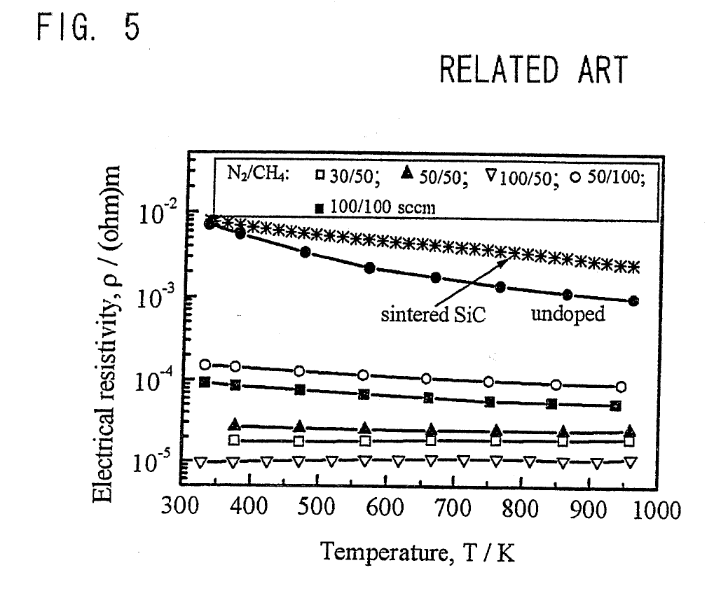

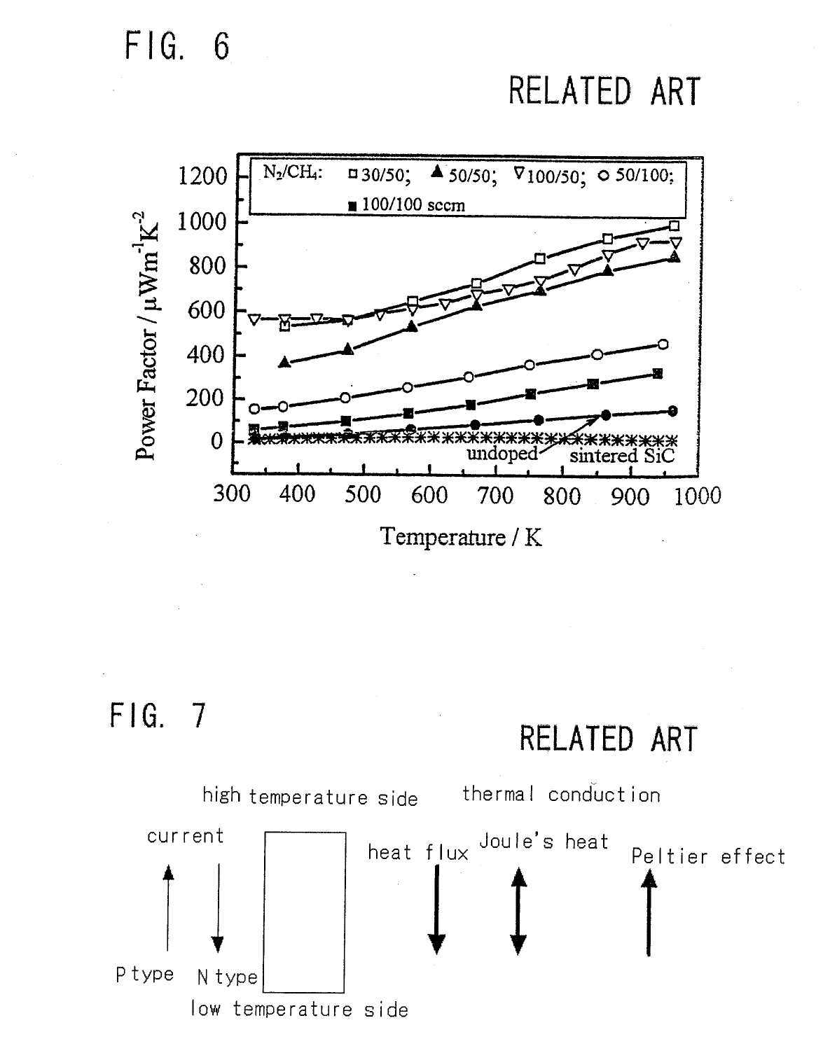

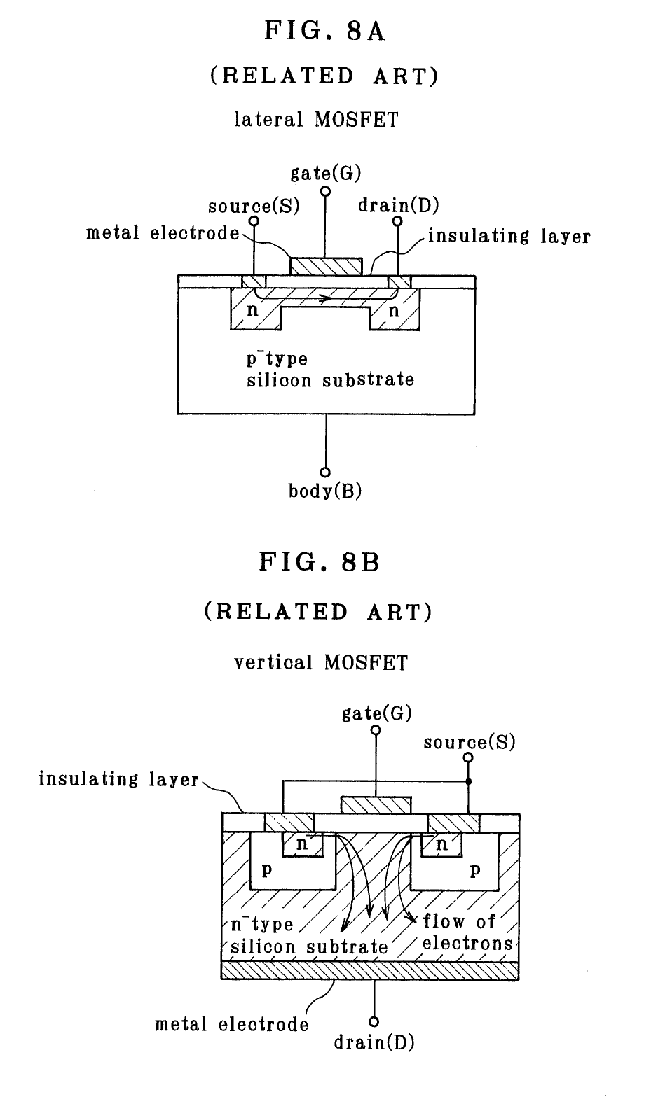

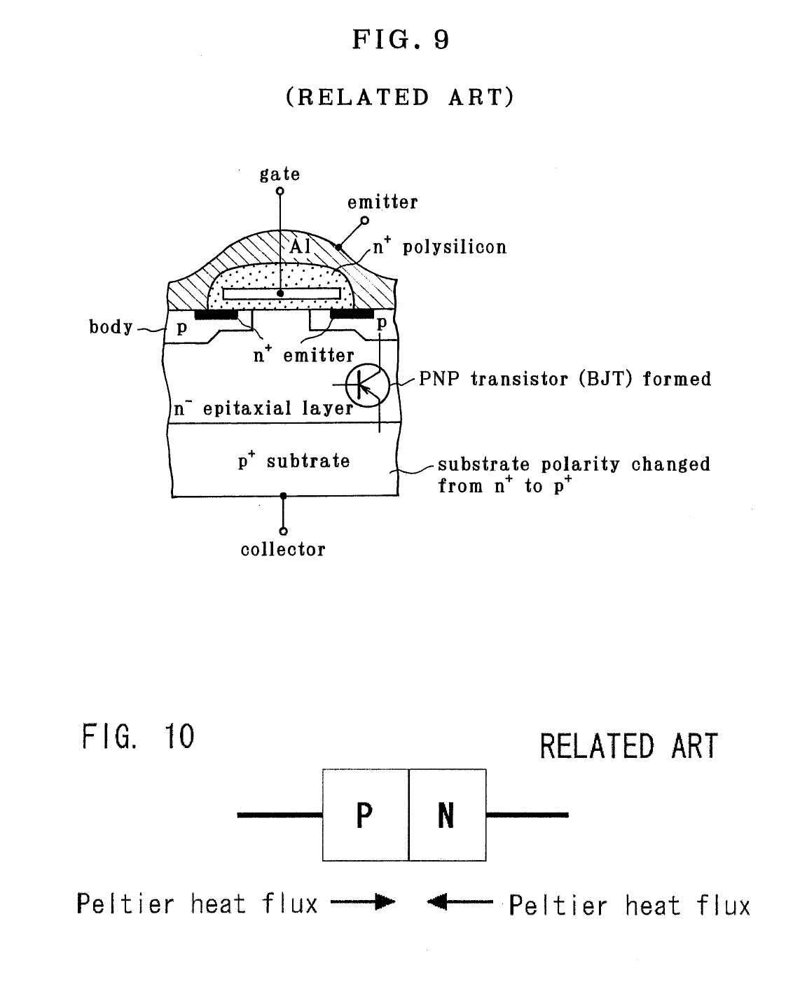

The electrical resistivity is now scrutinized. The electrical resistivity is varied appreciably with the mixing amount of impurities. With the N-type single crystal, the electrical resistivity is varied by a value from 1.0(−5) Wm to 6.6(−4) Wm in a range from 9.0(+20)/cm̂3 to 9.83(+17)/cm̂3. FIG.5 shows electrical resistivity of the N-type thin-film SiC (X. H. Wang et al., “Thermoelectric properties of SiC thick film deposited by thermal plasma physical vapor deposition”, Sci. Tech. Advanced Mat., vol. 4, pp. 167-172, 2003). This material also exhibits electrical resistivity ranging between 10(−2) Wm to 10(−5) Wm, depending on the amount of addition of the impurities. If the amount of the impurities in the material is increased, the electrical resistivity is lowered, thus showing the same tendency as the bulk material. However, the Seebeck coefficient of a sample with low resistivity is lowered, as may be seen from FIG.4, thus indicating the existence of an optimum value of the resistivity. It is difficult to measure the thermal conductivity of a thin film. No report on the thermal conductivity has been made in the Publications relevant to FIGS.4 and 5. It is not the coefficient of performance, as evaluated by the equation (5), but the power factor, of a plural number of thin films of SiC, that is the subject of comparison in the Publications. The power factor is defined as the equation (5) minus only the thermal conductivity. FIG.6 shows the power factor (X. H. Wang et al., “Thermoelectric properties of SiC thick film deposited by thermal plasma physical vapor deposition”, Sci. Tech. Advanced Mat., vol. 4, pp. 167-172, 2003).

The power factor value is compared to that of copper. The electrical conductivity of copper is 2.0(−8) Wm at 300 to 400K. On the other hand, the Seebeck coefficient of copper is on the order of 0.5 uV/K, so that its power factor is 1.25(−5) Wm⁻¹K⁻², which is about 1/30 of the value indicated by the power factor ∇ of FIG.6. Thus, if the thermal conductivity of SiC is of the same value as that of copper, SiC may be said to be a material which is more desirable than copper, insofar as the cooling is concerned.

A thin film SiC may be mounted on the surface of a copper electrode. SiC is used as a material of a heat sink, because its thermal conductivity is higher than that of aluminum, for instance. A cooling system that allows the current to flow as far as the heat sink is presupposed. The SiC plate, through which current flows, may be cooled with water.

An example in which the self-cooling system according to the present invention is applied to a PN junction device is now described. FIG.10 schematically shows the current flowing through a diode and the directions of the Peltier heat flow. In a diode, the directions of the Peltier heat flow flux by the current flowing therethrough are reversed in dependence upon the polarity of the semiconductor, so that two Peltier heat fluxes flow in opposite directions in the PN junction. The current flows through the diode (forward current) in an amount determined by the temperature at the PN junction. The PN junction is inherently depleted of carriers and hence is high in resistivity. In addition, the Joule's heat is generated by the resistance at the junction. Thus, the temperature of the PN junction is raised by increase in the amount of the current flowing through the diode to determine the maximum allowable value of the current flowing through the diode. Up to now, the diode is cooled by thermal conduction of the diode material itself. The thermal conduction of the diode is determined by the diode material. The thicknesses of the P-type element and the N-type element, schematically shown in FIG.10, differ from each other.

On a major surface layer of a semiconductor substrate of the N- or P-type, there is formed a layer of the opposite polarity to form the diode. Since the PN junction layer is close to this area of the reversed polarity, the thermal resistance is lowered to provide for effective cooling. This is a phenomenon observed in common in all of the constitutions of the semiconductor apparatus, having PN junctions, inclusive of constitutions in which an N-type layer or a P-type layer is formed in a well. With the IGBT, the phenomenon is observed at a junction between the collector side P-type substrate and the N-type epitaxial layer as the next layer.

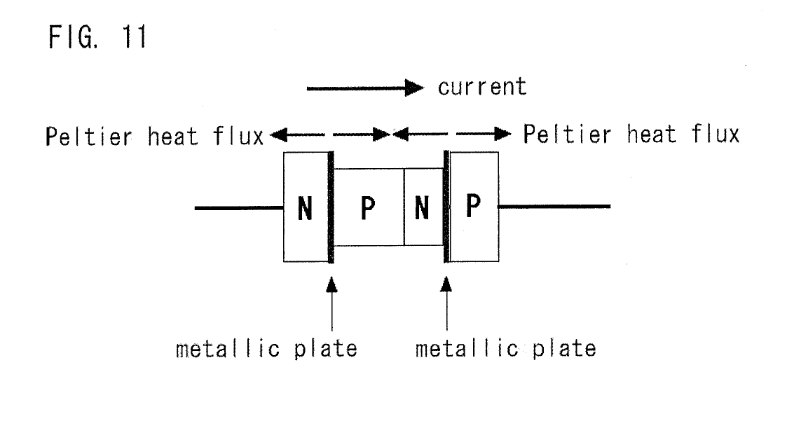

To provide the device having a PN junction with the Peltier cooling effect by the own current, in accordance with the present invention, the constitution shown in FIG.11 is used. To transport heat to outside the device by Peltier cooling, a P-layer and an N-layer are connected to two mid semiconductor layers of opposite polarities. Thin metal layers are provided in-between because the current ceases to flow at the junctions. By so doing, the current may flow through the junctions. Since metal has only low electrical resistivity, heat generation in the metallic layer is not of a problem. In FIG.11, an N-type thermoelectric semiconductor layer (Peltier element) is provided on the side of the P layer opposite to the PN junction, with the interposition of a metallic layer, whilst a P-type thermoelectric semiconductor layer (Peltier element) is provided on the side of the N layer opposite to the PN junction, with the interposition of a metallic layer. That is, two Peltier elements are provided on the P-layer and N-layer of the PN junction to permit the Peltier heat to be transported to outside the device. However, only one of the two Peltier elements may be sufficient.

One of the P and N layers is appreciably thinner than the other layer, as mentioned hereinabove. To this thin side is attached the Peltier cooling layer as shown in FIG.11. In general, the Peltier cooling layer is of a cross-sectional area larger than that of the PN device in order to further decrease the thermal resistance.

The self-cooling system according to the present invention may well be applied to the PN junction in a LED (Light Emitting Diode) or a semiconductor laser device. In this example, at least one of a P-type element and an N-type element which together form a PN junction in at least one of a LED (Light Emitting Diode) device and a semiconductor laser device, is provided with a thermoelectric semiconductor element of the polarity opposite to that of the aforementioned one element, with a metal layer in-between. The P-type element forming the PN junction together with the N-type element may be provided via a metal layer with an N-type thermoelectric semiconductor element on an upstream side of the current flowing through the PN junction. The N-type element forming the PN junction together with the P-type element may be provided via a metal layer with a P-type thermoelectric semiconductor element on a downstream side of the current flowing through the PN junction. When the current flows through said PN junction, the thermoelectric semiconductor element operates as a Peltier cooling element

In the present invention, materials other than silicon carbide (SiC) may as a matter of course be used as a Peltier element. Aluminum nitride (AlN) for example may also be used as a Peltier element for a self cooling system according to the present invention.

In case a semiconductor apparatus to be cooled is an IGBT, there is provided a conductive layer (metal layer) between the IGBT and the N-type material (102 in FIG.1 for example).

Although the present invention has so far been described with reference to preferred examples, the present invention is not to be restricted to the examples. It is to be appreciated that those skilled in the art can change or modify the examples without departing from the scope and spirit of the invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor apparatus comprising:
a semiconductor element; and
a cooling system that cools the semiconductor element utilizing current flowing through the semiconductor element.

2. The semiconductor apparatus according to claim 1, wherein said cooling system comprises an N-type material arranged in contact with said semiconductor element.

3. The semiconductor apparatus according to claim 1, wherein said cooling system comprises a material exhibiting relatively high thermal conductivity, relatively low electrical resistivity and a relatively high Seebeck coefficient.

4. The semiconductor apparatus according to claim 1, wherein said cooling system includes a metallic material.

5. The semiconductor apparatus according to claim 1, wherein said cooling system includes a copper alloy.

6. The semiconductor apparatus according to claim 1, wherein said cooling system comprises silicon carbide.

7. The semiconductor apparatus according to claim 1, wherein said cooling system includes aluminum nitride.

8. The semiconductor apparatus according to claim 1, wherein said semiconductor element includes a power MOSFET.

9. The semiconductor apparatus according to claim 8, wherein a semiconductor substrate of said power MOSFET is connected to a drain terminal of said power MOSFET via an N-type material.

10. The semiconductor apparatus according to claim 8, wherein a drain electrode of said power MOSFET includes an N-type material.

11. The semiconductor apparatus according to claim 1, wherein said semiconductor element includes an IGBT (Insulated Gate Bipolar Transistor).

12. The semiconductor apparatus according to claim 1, wherein said semiconductor element includes an IGBT (Insulated Gate Bipolar Transistor); and
said cooling system includes an N-type material arranged in contact with said IGBT via a metal layer.

13. The semiconductor apparatus according to claim 11, wherein a semiconductor substrate of said IGBT is connected to a collector terminal of said IGBT via an N-type material.

14. The semiconductor apparatus according to claim 11, wherein the collector electrode of said IGBT includes an N-type material.

15. The semiconductor apparatus according to claim 1, further comprising a heat sink of an N-type material.

16. A semiconductor apparatus comprising:
a PN junction; and
at least one thermoelectric element provided for at least one of a P-type element and an N-type element which form said PN junction;
said thermoelectric semiconductor element being of the polarity opposite to that of said one element.

17. The semiconductor apparatus according to claim 16, wherein the P-type element forming said PN junction together with said N-type element is provided via a metal with an N-type thermoelectric semiconductor element on an upstream side of the current flowing through said PN junction.

18. The semiconductor apparatus according to claim 16, wherein the N-type element forming said PN junction together with said P-type element is provided via a metal with a P-type thermoelectric semiconductor element on a downstream side of the current flowing through said PN junction.

19. The semiconductor apparatus according to claim 16, wherein, when the current flows through said PN junction, said thermoelectric semiconductor element operates as a Peltier cooling element.

20. The semiconductor apparatus according to claim 1, wherein said cooling system includes an N-type material with an area of cross section perpendicular to the direction of current flow being larger than an area of said semiconductor element arranged in contact with said N-type material.

21. A semiconductor apparatus comprising:
a semiconductor element including at least one of a diode, LED( light emitting diode) and a semiconductor laser; and
at least one thermoelectric element provided for at least one of a P-type element and an N-type element which form a PN junction in said semiconductor element;
said thermoelectric semiconductor element being of the polarity opposite to that of said one element.

22. The semiconductor apparatus according to claim 21, wherein the P-type element forming said PN junction together with said N-type element is provided via a metal with an N-type thermoelectric semiconductor element on an upstream side of the current flowing through said PN junction.

23. The semiconductor apparatus according to claim 21, wherein the N-type element forming said PN junction together with said P-type element is provided via a metal with a P-type thermoelectric semiconductor element on a downstream side of the current flowing through said PN junction.

24. The semiconductor apparatus according to claim 21, wherein, when the current flows through said PN junction, said thermoelectric semiconductor element operates as a Peltier cooling element.
